(19) United States
(12) Patent Application Publication
(10) Pub. No.: US 2026/0197935 A1
(43) Pub. Date: Jul. 9, 2026

(54) PRINTED CIRCUIT BOARDS WITH OPTICAL FIBERS

(71) Applicant: Aivres Systems Inc., San Jose, CA (US)

(72) Inventor: Chunghsing HAN, New Taipei City (TW)

(21) Appl. No.: 19/011,241

(22) Filed: Jan. 6, 2025

(51) Int. Cl. H05K 1/02; G02B 6/04; G02B 6/12; G02B 6/125

(52) U.S. Cl. CPC H05K 1/0274; G02B 6/04; G02B 6/125; H05K 1/0271; G02B 2006/12038; H05K 2201/10121

(57) ABSTRACT

Methods, devices, subsystems, systems, and techniques for printed circuit boards (PCBs) with optical fibers are provided. In one aspect, a device includes: a first layer having first electrically conductive traces, a second layer having second electrically conductive traces, and a core layer stacked between the first layer and the second layer. The core layer includes: a dielectric material filled in the core layer and groups of optical fibers that are embedded in the filled dielectric material and extend across the core layer.

### TECHNICAL FIELDS

The present disclosure is related to printed circuit boards (PCBs).

### BACKGROUND

Since artificial intelligence, cloud computing, and big data analytics all generate extremely high computing throughput, the bandwidth required for data storage and transmission may increase exponentially. As the speed of electronic signals transmitted on printed circuit boards becomes faster, the problem of signal attenuation becomes more serious.

### SUMMARY

The present disclosure describes methods, devices, subsystems, systems and techniques for printed circuit boards (PCBs) with optical fibers, e.g., using the optical fibers embedded in the PCBs for data transmission with high data rates, for example, for transmitting Peripheral Component Interconnect Express (PCIe) data according to a PCIe standard such as PCIe Gen 4, PCIe Gen 5, PCIe Gen 6, or even higher PCIe standard.

One aspect of the present disclosure features a device, including: a first layer including first electrically conductive traces; a second layer including second electrically conductive traces; and a core layer stacked between the first layer and the second layer. The core layer includes: a dielectric material filled in the core layer and groups of optical fibers that are embedded in the filled dielectric material and extend across the core layer.

In some implementations, the device further includes fiber connectors. Each of the fiber connectors is coupled to a respective group of the groups of optical fibers embedded in the filled dielectric material of the core layer. Each group of optical fibers has input ends coupled to a first fiber connector and output ends coupled to a second fiber connector.

In some implementations, the groups of optical fibers include a first group of optical fibers and a second group of optical fibers that are coupled together using a corresponding intermediate fiber connector of the fiber connectors.

In some implementations, the first layer, the core layer, and the second layer form a group of layers, and at least one of the first fiber connector or the second fiber connector is arranged on a side of the group of layers.

In some implementations, the device includes groups of layers each having the first layer, the core layer, and the second layer. At least one of the first fiber connector or the second fiber connector is arranged between two adjacent groups of layers.

In some implementations, at least one of the first fiber connector or the second fiber connector is arranged on or in the first layer.

In some implementations, the first layer, the core layer, and the second layer are stacked along a first direction, and the groups of optical fibers include first groups of optical fibers extending along a second direction perpendicular to the first direction and second groups of optical fibers extending along a third direction perpendicular to the first direction and the second direction. The core layer extends in a plane defined by the second direction and the third direction, the first direction being perpendicular to the plane.

In some implementations, the first groups of optical fibers are arranged along the third direction, and the second groups of optical fibers are arranged along the second direction, and the groups of optical fibers are interwoven in the core layer and configured to reinforce the core layer.

In some implementations, an optical fiber of the groups of optical fibers includes a core and a cladding layer surrounding the core. The optical fiber is configured to transmit light.

In some implementations, the optical fiber further includes a coating layer surrounding the cladding layer.

In some implementations, the optical fiber is a single-mode fiber (SMF) or a multi-mode fiber (MMF).

In some implementations, the core layer further includes fillers distributed within the filled dielectric material and around the groups of optical fibers.

In some implementations, the dielectric material includes a polymer material.

In some implementations, the core layer further includes glass fibers that are embedded in the filled dielectric material and extend across the core layer.

In some implementations, the glass fibers are interwoven with the groups of optical fibers in the core layer, and the glass fibers are configured to reinforce the core layer and have no connection to optical connectors.

In some implementations, the device further includes: one or more other core layers between the first layer and the second layer and one or more intermediate layers between the first layer and the second layer, each of the one or more intermediate layers being between two adjacent core layers.

In some implementations, the device is configured to be a printed circuit board (PCB).

Another aspect of the present disclosure features a device including: a printed circuit board (PCB) and circuits integrated on the PCB. The PCB includes: a first layer including first electrically conductive traces; a second layer including second electrically conductive traces; and a core layer stacked between the first layer and the second layer. The core layer includes: a dielectric material filled in the core layer and groups of optical fibers that are embedded in the filled dielectric material and extend across the core layer. The circuits are configured to communicate with one another using at least one of the groups of optical fibers in the core layer.

In some implementations, the PCB further includes fiber connectors, each of the fiber connectors is coupled to a respective group of the groups of optical fibers embedded in the filled dielectric material of the core layer, and each group of optical fibers has input ends coupled to a first fiber connector and output ends coupled to a second fiber connector.

In some implementations, the circuits include: a first optical circuit coupled to a corresponding first fiber connector of the fiber connectors; and a second optical circuit coupled to a corresponding second fiber connector of the fiber connectors. The first optical circuit and the second optical circuit are configured to transmit data through the corresponding first fiber connector, the corresponding second fiber connector, and at least one corresponding group of optical fibers coupled between the corresponding first fiber connector and the corresponding second fiber connector.

In some implementations, the circuits include: a first electrical circuit and a second electrical circuit. The device further includes: an electric-optical (E/O) converter coupled to the first electrical circuit and a corresponding first fiber connector of the fiber connectors, where the first electrical circuit is coupled to the corresponding first fiber connector through the E/O converter; a photodetector coupled to the second electrical circuit and a corresponding second fiber connector of the fiber connectors, where the second electrical circuit is coupled to the corresponding second fiber connector through the photodetector. The first electrical circuit is configured to transmit an electrical signal to the second electrical circuit through the E/O converter, the corresponding fiber connector, at least one corresponding group of optical fibers coupled between the corresponding first fiber connector and the corresponding second fiber connector, the corresponding second fiber connector, and the photodetector.

In some implementations, the circuits further include a third electrical circuit, and at least one of the first electrical circuit or the second electrical circuit is coupled to the third electrical circuit through at least one of one or more of the first electrically conductive traces or one or more of the second electrically conductive traces.

In some implementations, the first electrical circuit and the second electrical circuit are configured to transmit first electrical data with each other using a first data rate. The at least one of the first electrical circuit or the second electrical circuit is configured to transmit second electrical data with the third electrical circuit using a second data rate. The first data rate is greater than the second data rate.

In some implementations, the first electrical data is transmitted along a first data path, and the second electrical data is transmitted along a second data path, and the first data path is greater than the second data path.

In some implementations, the first electrical data is transmitted according to a Peripheral Component Interconnect Express (PCIe) standard. In some implementations, the first data rate is greater than 8 gigatransfers per second (GT/s).

In some implementations, the third electrical circuit includes a power supply circuit configured to provide a supply voltage, and the at least one of the one or more of the first electrically conductive traces or the one or more of the second electrically conductive traces includes a power supply trace and a ground trace.

In some implementations, the E/O converter is configured to convert the electrical signal into a corresponding optical signal, and the photodetector is configured to convert a received optical signal into a corresponding electrical signal.

In some implementations, the device further includes at least one of: a second photodetector coupled to the first electrical circuit, or a second E/O converter coupled to the second electrical circuit.

In some implementations, the circuits include: an optical circuit and an electrical circuit configured to communicate with each other through at least one corresponding group of optical fibers of the groups of optical fibers.

In some implementations, the device further includes: an electric-optical (E/O) converter coupled to the electrical circuit and a corresponding first fiber connector of the fiber connectors that is coupled to the at least one corresponding group of optical fibers. The optical circuit is coupled to a corresponding second fiber connector of the fiber connectors that is coupled to the at least one corresponding group of optical fibers, and the electrical circuit is configured to transmit an electrical signal to the optical circuit through the E/O converter, the corresponding first fiber connector, the at least one corresponding group of optical fibers, and the corresponding second fiber connector.

In some implementations, the device further includes: a photodetector coupled to the electrical circuit and a corresponding first fiber connector of the fiber connectors that is coupled to the at least one corresponding group of optical fibers. The optical circuit is coupled to a corresponding second fiber connector of the fiber connectors that is coupled to the at least one corresponding group of optical fibers. The optical circuit is configured to transmit an optical signal to the electrical circuit through the corresponding second fiber connector, the at least one corresponding group of optical fibers, the corresponding first fiber connector, and the photodetector.

In some implementations, the device is configured to be a Printed Circuit Board Assembly (PCBA), and the PCBA is configured to transmit PCIe data.

A further aspect of the present disclosure features a method, including: providing groups of optical fibers; forming a core layer by embedding the groups of optical fibers in a dielectric material, where the groups of optical fibers extend across the core layer; forming a first layer including first electrically conductive traces and a second layer including second electrically conductive traces; and integrating the first layer, the core layer, and the second layer together to form a device.

In some implementations, the device is a printed circuit board (PCB), and the method further includes: integrating circuits on the PCB. The circuits are configured to transmit with one another using at least one of the groups of optical fibers in the core layer.

The details of one or more implementations of the subject matter of this specification are set forth in the Detailed Description, the Claims, and the accompanying drawings. Other features, aspects, and advantages of the subject matter will become apparent to those of ordinary skill in the art from the Detailed Description, the Claims, and the accompanying drawings.

### DESCRIPTION OF DRAWINGS

FIG. 1 illustrates an example structure of printed circuit board (PCB) with optical fibers.

FIG. 2 illustrates an example PCB with optical fibers and fiber connector (Type 1).

FIG. 3 illustrates an example printed circuit board assembly (PCBA) with two optical circuits that communicate using a PCB with optical fibers.

FIG. 4 illustrates another example PCBA with an optical circuit and an electric circuit that communicate using a PCB with optical fibers.

FIG. 5 illustrates another example PCBA with two electrical circuits that communicate using a PCB with optical fibers.

FIG. 6 is a flowchart of an example process of a method of forming a PCB with optical fibers.

FIG. 7 is a flowchart of an example process of a method of forming a PCBA with optical fibers.

FIG. 8 is a block diagram illustrating an example of a computing system.

FIG. 9 is a block diagram illustrating an example of a computing device.

Like reference numbers and designations in the various drawings indicate like elements.

### DETAILED DESCRIPTION

Implementations of the present disclosure provide methods, devices, subsystems, systems and techniques for printed circuit boards (PCBs) with optical fibers, e.g., using the optical fibers embedded in the PCBs for data transmission with high data rates, for example, for transmitting Peripheral Component Interconnect Express (PCIe) data according to a PCIe standard such as PCIe Gen 4, PCIe Gen 5, PCI Gen 6, or even higher PCIe standard.

In PCIe technology, as the data transfer rate increases, so does the insertion loss. As shown in Table 1 below, PCIe version (or PCIe Gen) 6.0 has a higher transmission speed (64 gigatransfers per second-GT/s) compared to other PCIe versions such as PCIe Gen 3, PCIe Gen 4, and PCIe Gen 5. Accordingly, the PCIe Gen 6 has an insertion loss budget of 32 dB, which means that the total loss of the signal during transmission must not exceed 32 dB to maintain signal quality and the PCB trace lengths must not exceed a length threshold. Exceeding the length threshold may result in deterioration of signal quality and affect the reliability of data transmission. The possible PCB trace lengths may depend on a material of PCB board. For example, for PCIe Gen 6.0, to meet the insertion loss budget, the maximum trace length of a PCB board is 3.4 inches (8.64 cm) for using FR4 sheets as the PCB board, or 5 inches (12.7 cm) for using Megtron-6 sheets as the PCB board.

TABLE 1
Properties of different PCIe Versions

| PCIe version | Insertion | Possible PCB | | Possible PCB |
|---|---|---|---|---|
| (Transmission | Loss | trace lengths | | trace lengths |
| speed) | Budget | (FR4 sheets) | | (Megtron-6 sheets) |
| 3.x (8GT/s) | 22 dB | 17-35 | inches | 35 inches |
| 4.x (16GT/s) | 28 dB | 8 | inches | 15 inches |
| 5.x (32GT/s) | 36 dB | 4 | inches | 10 inches |
| 6.x (64GT/s) | 32 dB | 3.4 | inches | 5 inches |

On existing PCBs, the transmission distance of PCIe Gen4 signals can only reach 15 inches at most, and in the case of PCIe Gen5, the transmission distance can be further reduced to less than 10 inches. This is already the longest distance that can be achieved with ultra-low-loss boards, and even though the cost is more than several times that of existing PCBs, this signal distance is still far from what a server design requires.

Implementations of the present disclosure provide techniques that can address the problem of signal attenuation for high speed PCIe data transmission, e.g., by using optical fibers embedded in the printed circuit boards (PCBs). In some implementations, a printed circuit board (PCB) includes: a first layer having first electrically conductive traces, a second layer having second electrically conductive traces, and a core layer stacked between the first layer and the second layer. The core layer includes: a dielectric material filled in the core layer and groups of optical fibers that are embedded in the filled dielectric material and extend across the core layer. The PCB can include fiber connectors. Each of the fiber connectors is coupled to a respective group of the groups of optical fibers embedded in the filled dielectric material of the core layer, and each group of optical fibers has input ends coupled to a first fiber connector and output ends coupled to a second fiber connector. The PCB can be configured to transmit data between optical/photonic chips, between an optical chip and an electrical chip, and/or between two electrical chips, using optical fibers embedded in the PCB.

The subject matter described in the present disclosure can be implemented to realize one or more of the following technical advantages and/or benefits. For example, the techniques can address the signal attenuation problems that become serious as the speed of electronic signals transmitted on printed circuit boards becomes faster. Existing methods to improve this problem are to use low-loss boards or to add active chips (e.g., Retimer). Upgrading the PCB material from mid-loss to ultra-low-loss can reduce the problem of signal attenuation, but the cost can be greatly increased. Retimer is a high-speed serial/deserializer with digital signal processing (DSP) capability that can reconstruct clean PCIe signals even if the received PCIe signal has been coupled with noise and send a copy of the signal to the destination, but, if a Retimer chip is used, a channel needs to be split into two or more channel paths, and the Retimer chip needs to be added to each channel path, which can cause high power consumption and signal delay by the additional Retimer chip. Compared to using Retimer or low-loss boards, a PCB with integrated optical fibers implemented in the present disclosure can address the problem of signal attenuation without increasing production cost. The optical fibers can transmit optical signals with much higher transmission speed (e.g., 100 Gbps or higher), much lower signal loss, and much lower power consumption compared to transmitting electrical signals using metal traces in a conventional PCB. Moreover, the optical fibers can be used as reinforcing material in the PCB, because the reinforcing material in a conventional PCB and the optical fibers can both be essentially glass fiber filaments. Thus, the techniques can integrate the optical fibers in the PCB, which can be compatible with the existing manufacturing techniques to enable low cost and high mass production. The optical fibers can also leverage the advantages of glass fibers, including, but not limited to, 1) high stiffness, which provides high rigidity and prevents PCB deformation, 2) dimensional stability, 3) low coefficient of thermal expansion (CTE), which prevents internal circuit contacts inside the PCB from detaching and causing failure, 4) low warpage, which prevents board bending or warping, and 5) high Young's modules. The techniques implemented herein can be applied to all high-speed signal transmission PCB systems.

The following detailed description is presented to enable any person skilled in the art to make and use the disclosed subject matter in the context of one or more particular implementations. Various modifications, alterations, and permutations of the disclosed implementations can be made and will be readily apparent to those of ordinary skill in the art, and the general principles defined can be applied to other implementations and applications, without departing from the scope of the present disclosure. In some instances, one or more technical details that are unnecessary to obtain an understanding of the described subject matter and that are within the skill of one of ordinary skill in the art may be omitted so as to not obscure one or more described implementations. The present disclosure is not intended to be limited to the described or illustrated implementations, but to be accorded the widest scope consistent with the described principles and features.

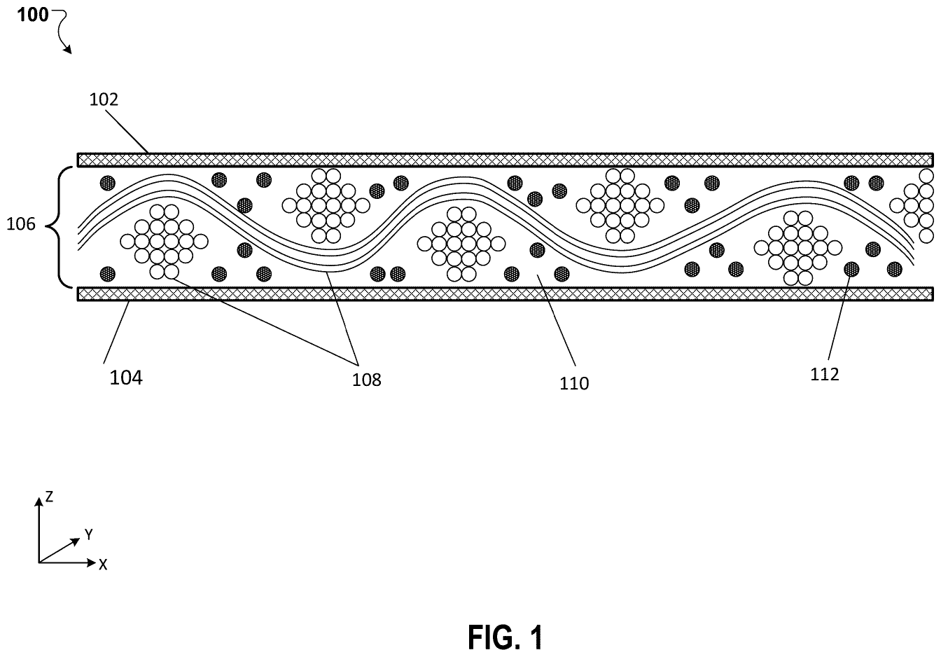

FIG. 1 illustrates an example structure 100 of a PCB with optical fibers 108. The optical fibers 108 is integrated (e.g., embedded) in the structure 100 of the PCB (or the PCB structure 100). The optical fibers 108 can transmit optical signals for high speed data transmission and can be also used as a reinforcing material for the PCB structure 100.

As illustrated in FIG. 1, the example PCB structure 100 includes a first layer 102, a second layer 104, and a core layer 106. The first layer 102 and second layer 104 each can be made of a thin metal sheet, such as copper foil. Electrically conductive traces can be created on each of the first layer 102 and second layer 104 to be used as conductive pathways for connecting electrical circuits or electrical components integrated on the PCB. These conductive pathways can serve as signal lines to transmit data signal or power signals.

As illustrated in FIG. 1, the core layer 106 can be stacked between the first layer 102 and the second layer 104. The core layer 106 can include a dielectric material 110 and groups of optical fibers 108 that are embedded in the dielectric material 110. The dielectric material 110 can form a matrix in the core layer 106.

The groups of optical fibers 108 extend across the core layer 106. The groups of optical fibers 108 can be interwoven with each other. In some implementations, the core layer 106 can further include glass fibers that are embedded in the filled dielectric material 110 and extend across the core layer 106. In some implementations, the glass fibers are interwoven with the groups of optical fibers 108 in the core layer 106, are configured to reinforce the core layer 106, and have no connection to optical connectors. The groups of optical fibers 108, and optionally with the addition of glass fibers, can serve as reinforcement and can have at least one of the following characteristics: 1) high stiffness, which provides high rigidity and prevents PCB deformation, 2) dimensional stability, 3) low coefficient of thermal expansion (CTE), which prevents internal circuit junctions from disconnecting, 4) low warpage, which prevents board bending or warping, and 5) high Young's modules.

In some implementations, an optical fiber in the groups of optical fibers 108 has a core and a cladding layer surrounding the core, and is configured to transmit light (or optical signals). The core of the optical fiber can be made of high-refractive index glass, and the cladding layer can be made of low refractive index glass or plastic to confine the light within the core by total internal reflection of light. The optical fiber can be a single-mode fiber (SMF) or a multi-mode fiber (MMF). An SMF allows a single optical mode of light to transmit, while an MMF allows multiple optical modes of light to transmit. In some examples, the core of the optical fiber can have a diameter in a range from 8 micrometers (μm) to 62.5 μm, and the cladding layer has a diameter of 125 μm. In some implementations, the optical fiber has double cladding layers. In some implementations, the optical fiber further has a coating layer that surrounds the cladding layer. The coating layer can be thinner or thicker. In some examples, an optical fiber that has a coating layer outside the cladding layer can have a diameter of 245 μm.

The dielectric material 110 can form a non-conductive substrate between the first layer 102 and the second layer 104. The dielectric material 110 can be a polymer material, such as epoxy resin, polyamide, or resin matrix. The dielectric material 110 can have at least one of the following characteristics: 1) heat resistance, which ensures the PCB does not delaminate after heating and soldering processes, 2) low water absorption, which prevents PCB delamination, 3) flame retardance, 4) high tear strength, 5) high glass transition temperature, which prevents delamination as materials with a high glass transition temperature are generally less water absorbent, 6) good resistance to impact, and 7) high dielectric strength, which provide for good insulating properties.

In some implementations, the core layer 106 further includes fillers 112 that can be distributed within the filled dielectric material 110 and around the groups of optical fibers 108. The fillers 112 have at least one of the following characteristics: 1) heat resistance, 2) low water absorption, 3) flame retardance, 4) high stiffness, 5) low CTE, 6) dimension stability, 7) low warpage, 8) high Young's modulus, and 9) high heat dissipation. In some examples, the fillers 112 include silica, boron nitride, or ceramic fillers.

In some implementations, the PCB can be a multi-layer PCB that has one or more other core layers between the first layer 102 and the second layer 104 and one or more intermediate layers between the first layer 102 and the second layer 104. Each of the one or more intermediate layers can be between two adjacent core layers. Each of the one or more other core layers can be same as, or similar to, the core layer 106 of FIG. 1.

The PCB with integrated optical fibers implemented in the present disclosure can be used as a motherboard that is a main circuit board that connects a computing system's internal components and external components, and can allow the internal components and/or the external components to communicate with each other. For example, the PCB with integrated optical fibers can be configured to connect one or more processors, memory devices, graphics cards, and other hardware.

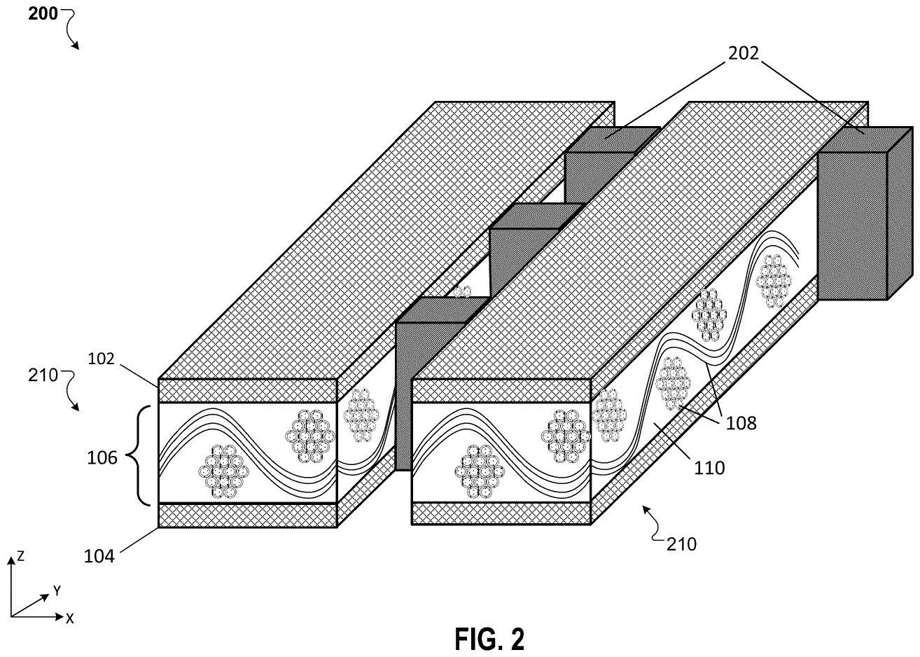

FIG. 2 illustrates an example PCB 200 with optical fibers 108 and fiber connectors 202. The PCB 200 can have groups 210 of layers. Each group 210 of layers can have a PCB structure 100 that includes a first layer 102, a core layer 106, and a second layer 104, as described in FIG. 1. Optical fibers 108 in a single group of layers 210 or optical fibers 108 among two or more groups 210 of layers can be connected with one another using the fiber connectors 202.

In the group 210 of layers, each of the layers can be stacked along a first direction (e.g., Z direction). The optical fibers 108 within the core layer 106 are formed by one or more first groups of optical fibers 108 that extend along a second direction (e.g., X direction) perpendicular to the first direction and one or more second groups of optical fibers that extend along a third direction (e.g., Y direction) perpendicular to both the first direction and second direction. The core layer 106 thus extends in a plane (e.g., XY plane) defined by the second direction and the third direction, the first direction being perpendicular to the plane. In some implementations, the groups of optical fibers 108 extending along the second and third directions respectively are interwoven in the core layer 106 and configured to reinforce the core layer 106.

The PCB 200 can further have fiber connectors 202. A fiber connector 202 can be configured to couple with optical fibers. The fiber connector 202 can be, e.g., a fiber array unit (FAU). Each of the fiber connectors can be coupled to a respective group of the groups of optical fibers 108 embedded in the filled dielectric material 110 of the core layer 106. Each group of optical fibers 108 has input ends coupled to a first fiber connector 202 and output ends coupled to a second fiber connector 202. The fiber connectors 202 can be arranged along an extending direction of the groups 210 of layers, e.g., the third direction such as Y direction. The groups of optical fibers 108 can include one group of optical fibers and another group of optical fibers that are coupled together using an intermediate fiber connector. In such a way, the groups of optical fibers 108 can be used to couple two circuits arranged with a long distance on a PCB board or on different PCB boards.

In some implementations, e.g., as illustrated in FIG. 2, at least one of the fiber connectors 202 is arranged on a side of a group 210 of layers. The fiber connector 202 can have a height substantially identical to a height of the group 210 of layers along the first direction. The fiber connector 202 arranged on the side of a group of layers can furthermore be between two adjacent groups of layers. The fiber connector 202 that is arranged on the side of a group of layers can be used as an optical fiber horizontal expansion to connect components in different groups 210 of layers in the PCB 200.

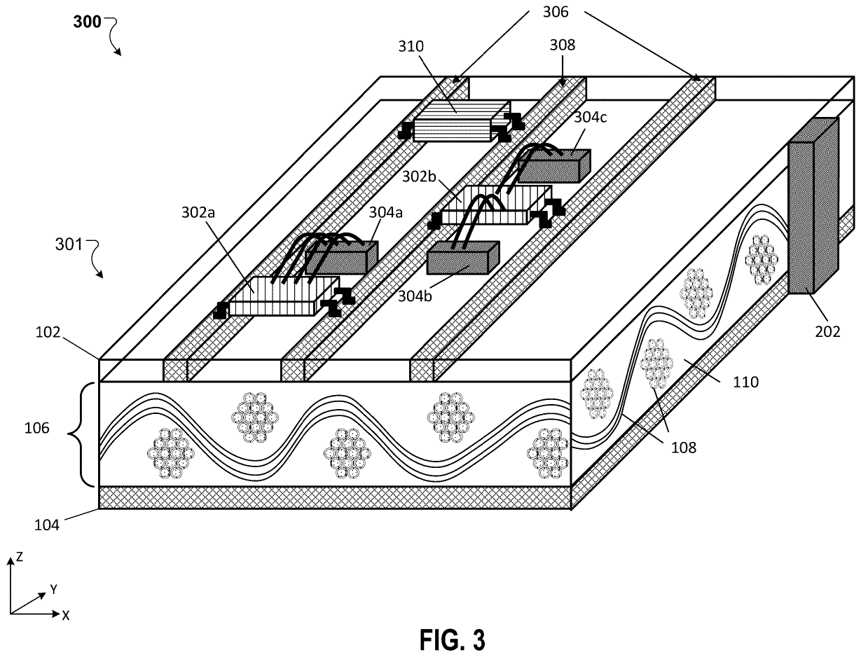

FIGS. 3, 4 and 5 illustrate different PCBA structures that each include a PCB (e.g., as described in FIG. 1 or 2) and circuits integrated on the PCB and configured to communicate with one another using at least one of groups of optical fibers embedded in the PCB. The PCB can further have fiber connectors that are each coupled to a respective group of the groups of optical fibers embedded in the PCB. The PCB can be same as, or similar to, the PCB of FIG. 1 or the PCB 200 of FIG. 2.

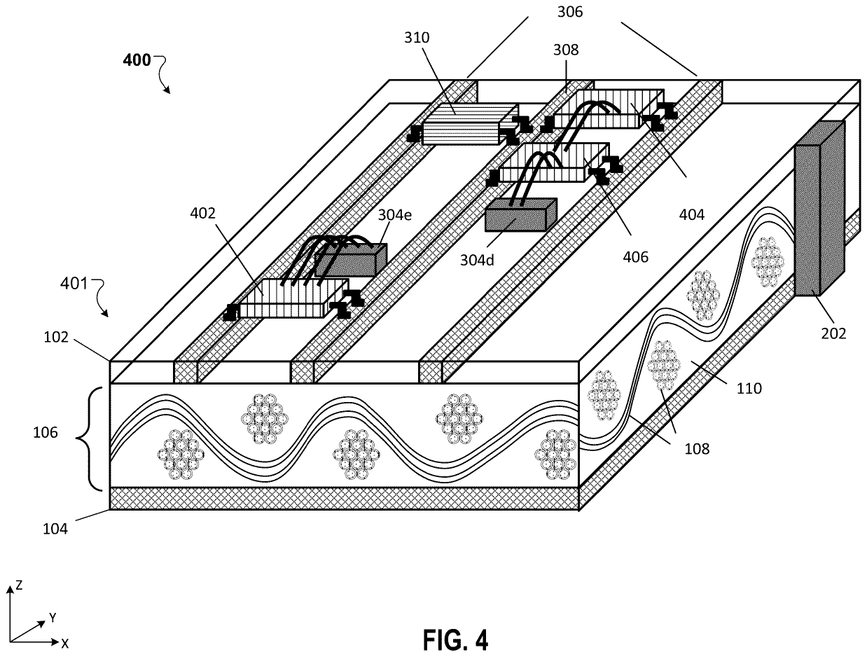

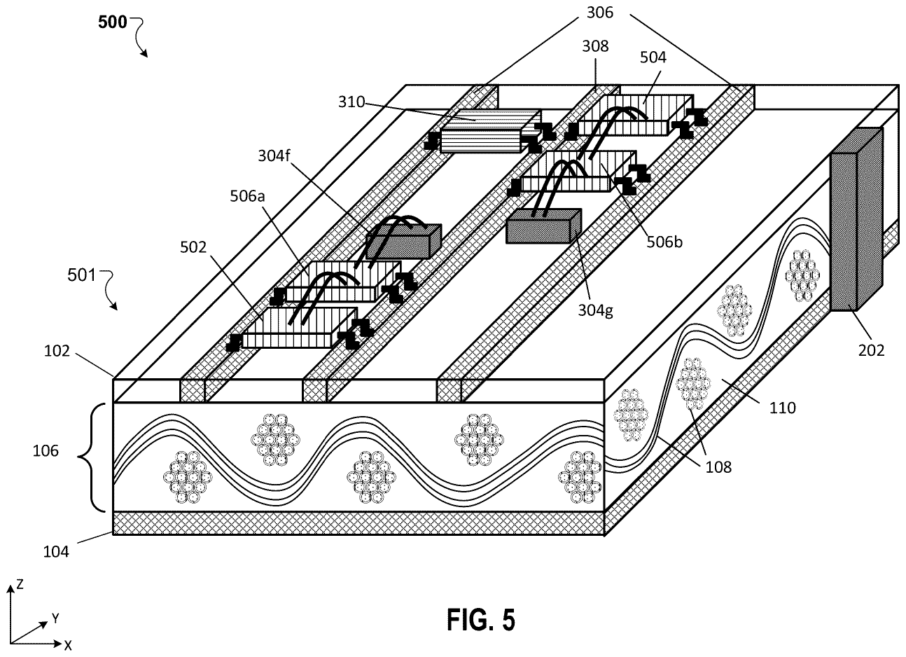

The PCB can be configured to transmit data (e.g., PCIe data) between optical/photonic circuits (e.g., as illustrated in FIG. 3), between optical circuits and electrical circuits (e.g., as illustrated in FIG. 4), or between electrical circuits (e.g., as illustrated in FIG. 5). In some implementations, a PCBA is configured with data communication between optical circuits, between electrical circuits, and/or between optical circuits and electrical circuits. The optical circuits and/or electrical circuits can be integrated in an optical chip (or photonic chip). The electrical circuits can be integrated in an electrical chip. Circuits integrated on the PCB for communication can be arranged at different locations on the PCB, e.g., with a distance greater than a threshold such as 10 inches, 15 inches, 20 inches, 25 inches, 30 inches, 35 inches, 40 inches, or even longer.

FIG. 3 illustrates an example PCBA 300 with two optical circuits 302 communicating using a PCB 301 integrated with optical fibers. The PCB 301 can have a structure (e.g., the structure 100 of FIG. 1), and can be same as, or similar to, the PCB 200 of FIG. 2.

In addition to one or more fiber connectors (type 1) 202 as described in FIG. 2 that can be arranged on a side of a group of layers or between two adjacent groups of layers, the PCB 301 can also include one or more fiber connectors (type 2) 304a, 304b, 304c (referred to generally as fiber connectors 304 and individually as a fiber connector 304) that are arranged on or in a first layer 102 of the PCB 301. A fiber connector 304 arranged on or in the first layer 102 of the PCB 301 can be coupled to input ends of a group of optical fibers or coupled to output ends of a group of optical fibers.

Circuits integrated on the PCB 301 can include first and second optical circuits 302a, 302b (referred to generally as optical circuits 302 and individually as an optical circuit 302) that are arranged at different locations on the PCB 301, e.g., with a distance greater than a threshold such as 10 inches, 15 inches, 20 inches, 25 inches, 30 inches, 35 inches, 40 inches, or even longer. The first optical circuit 302a can be coupled to a corresponding first fiber connector 304a. The second optical circuit 302b can be coupled to a corresponding second fiber connector 304b. Each optical circuit 302 can be coupled to a corresponding fiber connector 304 using a suitable coupling mechanism, e.g., fiber coupling, waveguide coupling, or optical grating coupling. One or more groups of optical fibers 108 can couple the two corresponding fiber connectors 304a, 304b. In such a way, the first optical circuit 302a and the second optical circuit 302b can be configured to transmit data omnidirectionally or bidirectionally through the first corresponding fiber connector 304a, the second corresponding fiber connector 304b, and at least one corresponding group of optical fibers 108 coupled between the corresponding first fiber connector 304a and the corresponding second fiber connector 304b. In some implementations, the second optical circuit 302b is further coupled to a third fiber connector 304c that can be coupled to a new group of optical fibers 108, such that the second optical circuit 302b can communicate with another circuit through the new group of optical fibers 108.

In some implementations, each of the first layer 102 and the second layer 104 can include one or more electrically conductive traces 306, 308. For example, the trace 306 can be a ground trace coupled to a ground, and the trace 308 can be a power trace. Circuits integrated on the PCB 301 can have pins coupled to the traces 306, 308 for transmission of electrical data or signals. In some examples, a third circuit 310 is integrated on the PCB 301. The third circuit 310 can be an electrical circuit. For example, the third circuit 310 can be a power supply circuit configured to provide a supply voltage to at least one of the optical circuits 302 on the PCB 301 through the traces 306, 308 on the first layer 102.

FIG. 4 illustrates another example PCBA 400 having an optical circuit 402 and an electric circuit 404 that communicate with each other using a PCB 401 integrated with optical fibers, e.g., through at least one group of optical fibers embedded in the PCB 401. The PCB 401 can have a structure (e.g., the structure 100 of FIG. 1), and can be same as, or similar to, the PCB 200 of FIG. 2 or the PCB 301 of FIG. 3.

In some implementations, to transmit an electrical signal from the electrical circuit 404 to the optical circuit 402, the electrical signal can be first converted into an optical signal, e.g., by a converter 406 such as an electric-optical (E/O) converter. The converter 406 can be coupled between the electrical circuit 404 and a corresponding fiber connector 304d that is coupled to at least one corresponding group of optical fibers 108 in the PCB 401. The optical circuit 402 can be directly coupled to a corresponding second fiber connector 304e that is coupled to the at least one corresponding group of optical fibers 108 coupled to the corresponding fiber connector 304e. Thus, the electrical circuit 404 can be configured to transmit an electrical signal to the optical circuit 402 through the converter 406, the corresponding first fiber connector 304d, the at least one corresponding group of optical fibers 108, and the corresponding second fiber connector 304e.

In some implementations, to transmit an optical signal from the optical circuit 402 to the electrical circuit 404, an optical-electrical converter 406 (e.g., O/E converter such as a photodetector) can be coupled to the electrical circuit 404. The optical signal can be transmitted from the optical circuit 402 through a corresponding second fiber connector 304e, at least one corresponding group of optical fibers 108 in the PCB coupled to the corresponding second fiber connector 304e, a corresponding first fiber connector 304d coupled to the at least one corresponding group of optical fibers 108 and the O/E converter 406, to the electrical circuit 404. In some examples, the E/O converter and the O/E converter are different components and separately coupled to the electrical circuit 404. In some examples, the E/O converter and the O/E converter are integrated together. The first and second fiber connector 304d, 304e can be same as, or similar to, the fiber connector 304a, 304b, or 304c of FIG. 3.

FIG. 5 illustrates another example PCBA 500 with two electrical circuits 502, 504 that communicate using a PCB 501 with integrated optical fibers. The PCBA 500 can be similar to the PCBA 300 of FIG. 3 or the PCBA 400 of FIG. 4. The PCB 501 can have a structure (e.g., the structure 100 of FIG. 1), and can be same as, or similar to, the PCB 200 of FIG. 2, the PCB 301 of FIG. 3, or the PCB 401 of FIG. 4.

For an electrical signal to be transmitted from a first electrical circuit 502 to a second electrical circuit 504, a converter 506a (e.g., an E/O converter such as the E/O converter 406 of FIG. 4) can be coupled between the first electrical circuit 502 and a corresponding first fiber connector 304f (e.g., the fiber connector 304 of FIG. 3 or 4). The converter 506a can convert the electrical signal from the first electrical circuit 502 into an optical signal that can be transmitted by the corresponding first fiber connector 304f to at least one first corresponding group of optical fibers 108 coupled to the corresponding first fiber connector 304f. A converter 506b (e.g., an O/E converter such as a photodetector) can be coupled between the second electrical circuit 504 and a corresponding second fiber connector 304g (e.g., the fiber connector 304 of FIG. 3 or 4) coupled to the at least one corresponding group of optical fibers 108. The converter 506b can convert a corresponding optical signal transmitted from the at least one first corresponding group of optical fibers 108 and the converter 506b into a corresponding electrical signal to the second electrical circuit 504. Thus, the first electrical circuit 502 can transmit the electrical signal to the second electrical circuit 504 through the E/O converter 506a, the corresponding first fiber connector 304f, the at least one first corresponding group of optical fibers 108, the corresponding second fiber connector 304g, and the photodetector 506b. In such a way, an electrical signal can therefore be transmitted from the first electrical circuit 502 to the second electrical circuit 504 using at least a group of optical fibers, which can greatly increase the transmission speed and reduce attenuation loss compared to electrical transmission of the electrical signal.

For an electrical signal to be also transmitted in an opposite direction from the second electrical circuit 504 to the first electrical circuit 502, e.g., for bidirectional communication, the first electrical circuit can be coupled to a second photodetector and the second electrical circuit can be coupled to a second E/O converter. The second E/O converter couples the second electrical circuit 504 to a corresponding third fiber connector (e.g., the fiber connector 304 of FIG. 3 or 4) that is coupled to at least one second corresponding group of optical fibers 108. The second photodetector couples the first electrical circuit to a corresponding fourth fiber connector (e.g., the fiber connector 304 of FIG. 3 or 4) coupled to the at least one second corresponding group of optical fibers 108. The second electrical circuit 504 can thus also be configured to transmit an electrical signal to the first electrical signal 502 through the second E/O converter coupled to the second electrical circuit, the corresponding third fiber connector coupled to the second E/O converter, the at least one second corresponding group of optical fibers 108 coupled between the third and fourth fiber connectors, the fourth corresponding fiber connector coupled to the second photodetector, and the second photodetector coupled to the first electrical circuit 502.

In some implementations, the corresponding third fiber connector and the corresponding second fiber connector are included in a same fiber connector, the corresponding fourth fiber connector and the corresponding first fiber connector are included in a same fiber connector, and the at least one first corresponding group of optical fibers is same as the at least one second corresponding group of optical fibers. In some implementations, the corresponding third fiber connector is different from the corresponding second fiber connector, the corresponding fourth fiber connector is different from the corresponding first fiber connector, and the at least one first corresponding group of optical fibers is different from the at least one second corresponding group of optical fibers.

In some implementations, circuits integrated on the PCB 501 further includes a third electrical circuit 310 that at least one of the first electrical circuit 502 or the second electrical circuit 504 is coupled to through at least one of one or more of the electrically conductive traces on the first layer 102 or one or more of the electrically conductive traces on the second layer 104.

In some implementations, the third electrical circuit 508 can include a power supply circuit configured to provide a supply voltage. At least one of the one or more electrically conductive traces on the first layer 102 of the PCB or the one or more electrically conductive traces on the second layer 104 of the PCB includes a power supply trace 306 and a ground trace 308.

In some implementations, at least one of the first electrical circuit 502 or the second electrical circuit 504 can be configured to transmit electrical data to the third electrical circuit 508 at a lower data rate than the data rate at which the first electrical circuit and the second electrical circuit 502 are configured to transmit electrical data with each other using optical fibers 108 in the PCB 501. That is, at least one of the first electrical circuit 502 or the second electrical circuit 504 can transmit electrical data through at least a group of optical fibers 108 to the other at a greater data rate than the data rate at which at least one of the first electrical circuit or the second electrical circuit transmits electrical data through at least one or more of the electrically conductive traces to the third electrical circuit 508. The electrical data that is transmitted by the first electrical circuit or the second electrical circuit to the other can be transmitted according to a PCIe standard (e.g., PCIe Gen 4 (16 GT/s), PCIe Gen 5 (32 GT/s), PCIe Gen 6 (64 GT/s), or higher). The data rate at which electrical data is transmitted by the first electrical circuit or the second electrical circuit to the other can be greater than 8 gigatransfers per second (GT/s).

The data path between the first electrical circuit 502 and the second electrical circuit 504 that is used to transmit electrical data through at least a group of optical fibers 108 can be greater than the data path between the third electrical circuit 508 and the first or second electrical circuit 502, 504 that is used to transmit electrical data through at least one or more of the electrically conductive traces. For example, the data path between the first electrical circuit and the second electrical circuit can be longer than 15 inches, 20 inches, 25 inches, 30 inches, 35 inches, 40 inches, or more.

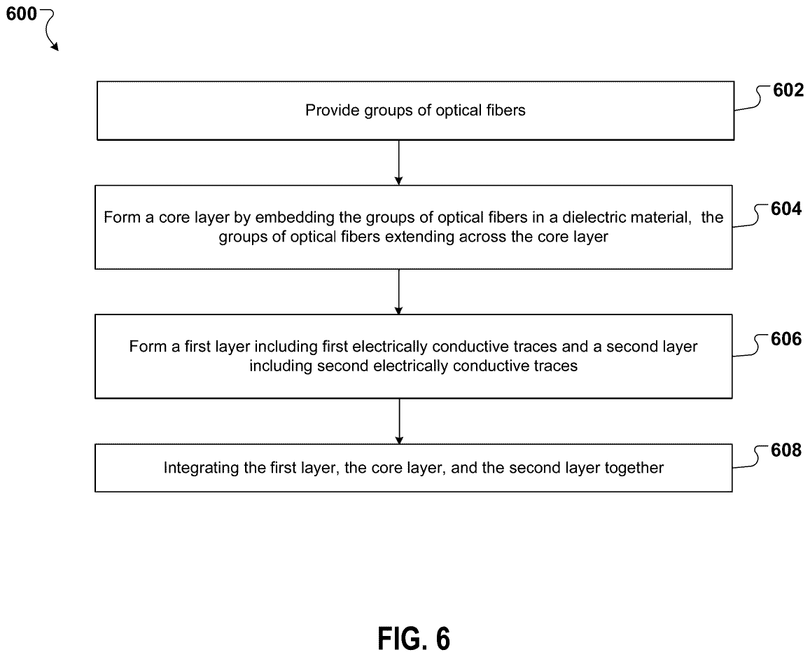

FIG. 6 is a flowchart of an example fabrication process 600 of forming a PCB with optical fibers. The PCB can have a structure (e.g., the structure 100 of FIG. 1), and can be same as, or similar to, the PCB 200 of FIG. 2, the PCB 301 of FIG. 3, the PCB 401 of FIG. 4, or the PCB 501 of FIG. 5. The optical fibers can be the optical fibers 108 of FIGS. 1 to 5.

At 602, groups of optical fibers are provided. An optical fiber includes a core and a cladding layer surrounding the core. The optical fiber is configured to transmit light. The optical fiber can be a single-mode fiber (SMF) or a multi-mode fiber (MMF). In some implementations, the optical fiber further includes a coating layer surrounding the cladding layer.

At 604, the groups of optical fibers provided are taken to form a core layer (e.g., the core layer 106 of FIGS. 1 to 5) by embedding the groups of optical fibers in a dielectric material (e.g., the dielectric material 110 of FIGS. 1 to 5). The dielectric material can be a polymer material such as epoxy resin, polyimide, or resin matrix. The groups of optical fibers can be braided to form an optical fiber network and then pressed with the dielectric material. The groups of optical fibers extend across the core layer. In some implementations, the core layer further includes fillers (e.g., the fillers 112 of FIG. 1) distributed within the filled dielectric material and around the groups of optical fibers.

At 606, a first layer including first electrically conductive traces and a second layer including second electrically conductive traces are formed. The first layer can be the first layer 102 of FIGS. 1 to 5, and the second layer can be the second layer 104 of FIGS. 1 to 5.

At 608, the first layer, the core layer, and the second layer are integrated together to form the PCB with the integrated optical fibers or a PCB structure (e.g., the PCB structure 100 of FIG. 1).

In some implementations, the first layer, the core layer, and the second layer are stacked along a first direction, and the groups of optical fibers include first groups of optical fibers extending along a second direction perpendicular to the first direction and second groups of optical fibers extending along a third direction perpendicular to the first direction and the second direction. The core layer extends in a plane defined by the second direction and the third direction, the first direction being perpendicular to the plane. In some implementations, the first groups of optical fibers are arranged along the third direction, and the second groups of optical fibers are arranged along the second direction, and the groups of optical fibers are interwoven in the core layer and configured to reinforce the core layer.

In some implementations, the process 600 further includes: forming one or more other core layers between the first layer and the second layer and one or more intermediate layers between the first layer and the second layer, each of the one or more intermediate layers being between two adjacent core layers.

In some implementations, the process 600 further includes forming fiber connectors (e.g., the fiber connectors 202 of FIGS. 2 to 5 and/or the fiber connectors 304 of FIGS. 3 to 5). Each of the fiber connectors is coupled to a respective group of the groups of optical fibers embedded in the filled dielectric material of the core layer. Each group of optical fibers has input ends coupled to a first fiber connector and output ends coupled to a second fiber connector. In some implementations, the groups of optical fibers include a first group of optical fibers and a second group of optical fibers that are coupled together using a corresponding intermediate fiber connector of the fiber connectors.

In some implementations, the first layer, the core layer, and the second layer form a group of layers, and at least one of the first fiber connector or the second fiber connector is arranged on a side of the group of layers, e.g., as illustrated in FIG. 2. In some implementations, at least one of the first fiber connector or the second fiber connector is arranged between two adjacent groups of layers, e.g., as illustrated in FIG. 2. In some implementations, at least one of the first fiber connector or the second fiber connector is arranged on or in the first layer, e.g., as illustrated in FIG. 3, 4, or 5.

In some implementations, the core layer further includes glass fibers that are embedded in the filled dielectric material and extend across the core layer. In some implementations, the glass fibers are interwoven with the groups of optical fibers in the core layer, and the glass fibers are configured to reinforce the core layer and have no connection to fiber connectors.

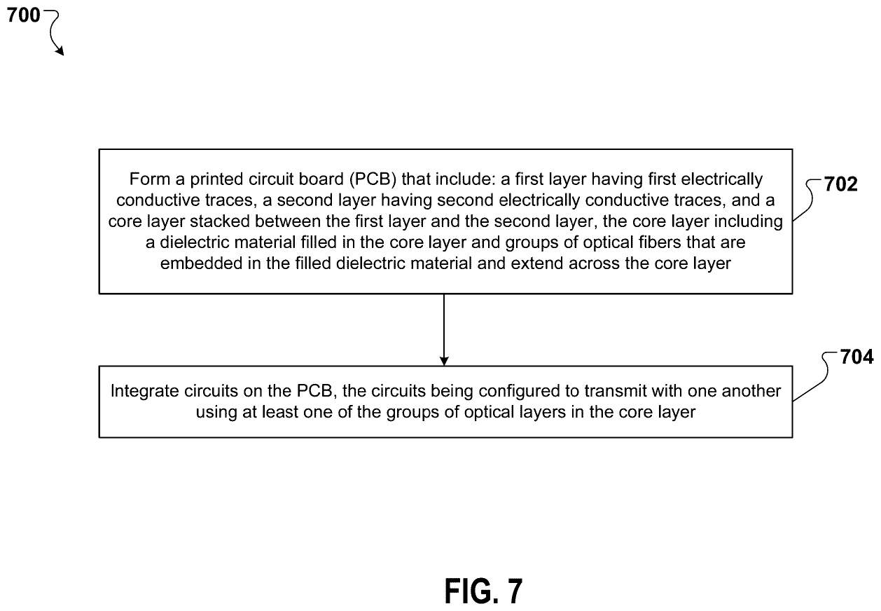

FIG. 7 is a flowchart of an example fabrication process 700 of forming a PCBA with optical fibers. The PCBA can be implemented as the PCBA 300 of FIG. 3, 400 of FIG. 4, or 500 of FIG. 5. The optical fibers can be the optical fibers 108 of FIGS. 1 to 5.

At 702, a PCB is formed, e.g., according to the process 600 of FIG. 6. The PCB can have a structure (e.g., the structure 100 of FIG. 1), and can be same as, or similar to, the PCB 200 of FIG. 2, the PCB 301 of FIG. 3, the PCB 401 of FIG. 4, or the PCB 501 of FIG. 5. In some implementations, the PCB includes a first layer having first electrically conductive traces (e.g., the first layer 102 of FIGS. 1 to 5), a second layer having second electrically conductive traces (e.g., the second layer 104 of FIGS. 1 to 5), and a core layer (e.g., the core layer 106 of FIGS. 1 to 5). The core layer is stacked between the first layer and the second layer. The core layer can include a dielectric material (e.g., the dielectric material 110 of FIGS. 1 to 5) filled in the core layer and groups of optical fibers that are embedded in the filled dielectric material and extend across the core layer.

In some implementations, the PCB further includes fiber connectors (e.g., the fiber connectors 202 of FIGS. 2 to 5 and/or the fiber connectors 304 of FIGS. 3 to 5). Each of the fiber connectors is coupled to a respective group of the groups of optical fibers embedded in the filled dielectric material of the core layer. Each group of optical fibers can have input ends coupled to a first fiber connector and output ends coupled to a second fiber connector.

At 704, circuits are integrated on the PCB to form the PCBA. The circuits can be configured to transmit with one another using at least one of the groups of optical fibers in the core layer. The circuits can be integrated on the PCB using various PCB soldering techniques, such as Surface-Mount Technology (SMT), through-hole, or hand soldering.

In some implementations, the circuits include: a first optical circuit (e.g., the optical circuit 302 of FIG. 3) coupled to a corresponding first fiber connector (e.g., the fiber connector 304a of FIG. 3) of the fiber connectors and a second optical circuit (e.g., the optical circuit 304 of FIG. 3) coupled to a corresponding second fiber connector (e.g., the fiber connector 304b) of the fiber connectors, e.g., as illustrated in FIG. 3. The first optical circuit and the second optical circuit are configured to transmit data through the corresponding first fiber connector, the corresponding second fiber connector, and at least one corresponding group of optical fibers coupled between the corresponding first fiber connector and the corresponding second fiber connector.

In some implementations, the circuits include: a first electrical circuit and a second electrical circuit (e.g., the electrical circuits 502, 504 of FIG. 5). The circuits can further include: an electric-optical (E/O) converter (e.g., the E/O converter 506a of FIG. 5) coupled to the first electrical circuit and a corresponding first fiber connector of the fiber connectors. The first electrical circuit is coupled to the corresponding first fiber connector through the E/O converter. The circuits can further include a photodetector (e.g., the converter 506b of FIG. 5) coupled to the second electrical circuit and a corresponding second fiber connector of the fiber connectors. The second electrical circuit is coupled to the corresponding second fiber connector through the photodetector. The first electrical circuit is configured to transmit an electrical signal to the second electrical circuit through the E/O converter, the corresponding fiber connector, at least one corresponding group of optical fibers coupled between the corresponding first fiber connector and the corresponding second fiber connector, the corresponding second fiber connector, and the photodetector.

In some implementations, the circuits further include a third electrical circuit (e.g., the third electrical circuit 310 of FIG. 3, 4, or 5). At least one of the first electrical circuit or the second electrical circuit can be coupled to the third electrical circuit through at least one of one or more of the first electrically conductive traces or one or more of the second electrically conductive traces.

In some implementations, the first electrical circuit and the second electrical circuit are configured to transmit first electrical data with each other using a first data rate. The at least one of the first electrical circuit or the second electrical circuit is configured to transmit second electrical data with the third electrical circuit using a second data rate. The first data rate is greater than the second data rate. In some implementations, the first electrical data is transmitted along a first data path, and the second electrical data is transmitted along a second data path, and the first data path is greater than the second data path. In some implementations, the first electrical data is transmitted according to a Peripheral Component Interconnect Express (PCIe) standard. In some implementations, the first data rate is greater than 8 gigatransfers per second (GT/s). In some implementations, the PCBA is configured to transmit PCIe data according to a PCIe standard, e.g., PCIe Gen 4 (16 GT/s), PCIe Gen 5 (32 GT/s), PCIe Gen 6 (64 GT/s), or higher.

In some implementations, the third electrical circuit includes a power supply circuit configured to provide a supply voltage, and the at least one of the one or more of the first electrically conductive traces or the one or more of the second electrically conductive traces includes a power supply trace (e.g., 308 of FIG. 3, 4, or 5) and a ground trace (e.g., 306 of FIG. 3. 4, or 5).

In some implementations, the E/O converter is configured to convert the electrical signal into a corresponding optical signal, and the photodetector is configured to convert a received optical signal into a corresponding electrical signal. In some implementations, the circuits further includes at least one of: a second photodetector coupled to the first electrical circuit, or a second E/O converter coupled to the second electrical circuit.

In some implementations, the circuits include: an optical circuit (e.g., the optical circuit 402 of FIG. 4) and an electrical circuit (e.g., the electrical circuit 404 of FIG. 4) configured to communicate with each other through at least one corresponding group of optical fibers of the groups of optical fibers, e.g., as illustrated in FIG. 4.

In some implementations, the circuits further include: an electric-optical (E/O) converter (e.g., the E/O converter 406 of FIG. 4) coupled to the electrical circuit and a corresponding first fiber connector (e.g., the fiber connector 304d of FIG. 4) of the fiber connectors that is coupled to the at least one corresponding group of optical fibers. The optical circuit is coupled to a corresponding second fiber connector (e.g., the fiber connector 304e of FIG. 4) of the fiber connectors that is coupled to the at least one corresponding group of optical fibers. The electrical circuit is configured to transmit an electrical signal to the optical circuit through the E/O converter, the corresponding first fiber connector, the at least one corresponding group of optical fibers, and the corresponding second fiber connector.

In some implementations, the circuits further include: a photodetector coupled to the electrical circuit and a corresponding first fiber connector of the fiber connectors that is coupled to the at least one corresponding group of optical fibers. The optical circuit is coupled to a corresponding second fiber connector of the fiber connectors that is coupled to the at least one corresponding group of optical fibers. The optical circuit is configured to transmit an optical signal to the electrical circuit through the corresponding second fiber connector, the at least one corresponding group of optical fibers, the corresponding first fiber connector, and the photodetector.

The techniques implemented in the present disclosure can be applied to systems including one or more host devices (e.g., a server using one or more PCBs with integrated optical fibers, or a computer using a PCB with integrated optical fibers).

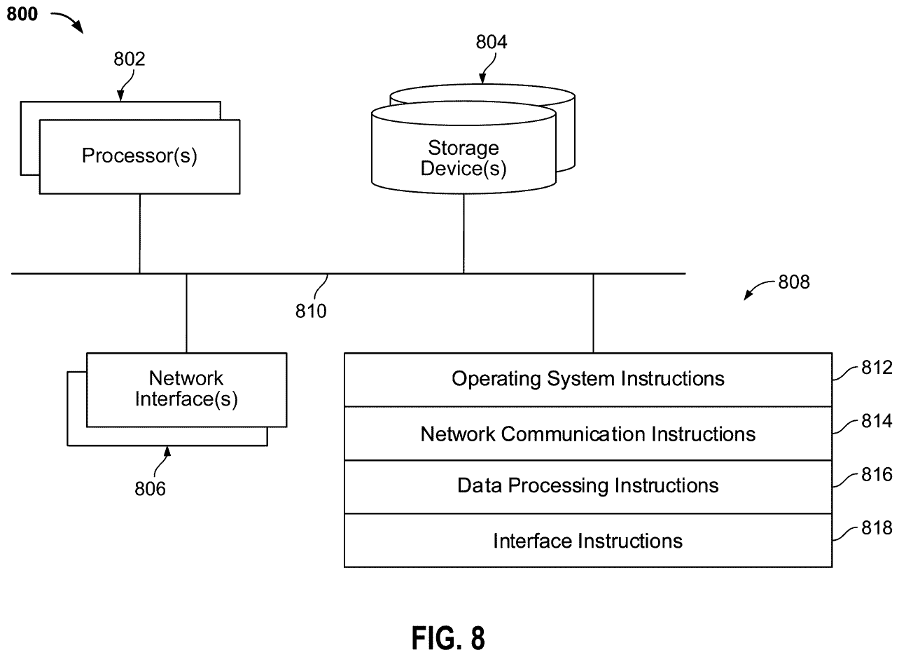

FIG. 8 is a block diagram illustrating an example architecture 800 of a computing system used to provide computational functionalities associated with described algorithms, methods, functions, processes, flows, and procedures. Other architectures are possible, including architectures with more or fewer components.

In some implementations, architecture 800 includes one or more processor(s) 802 (e.g., dual-core Intel® Xeon® Processors), one or more network interface(s) 806, one or more storage device(s) 804 (e.g., hard disk, optical disk, flash memory) and one or more computer-readable medium(s) 808 (e.g., hard disk, optical disk, flash memory, etc.). These components can exchange communications and data over one or more communication channel(s) 810 (e.g., buses), which can utilize various hardware and software for facilitating the transfer of data and control signals between components.

The architecture 800 includes one or more PCBs (e.g., the PCB of FIG. 1, the PCB 200 of FIG. 2, the PCB 301 of FIG. 3, the PCB 401 of FIG. 4, or the PCB 501 of FIG. 5). The one or more processors 802, the one or more network interface(s) 806, the one or more storage device(s) 804, and/or the one or more computer-readable medium(s) 808 can be integrated on the one or more PCBs and can communicate using the one or more PCBs.

The term “computer-readable medium” refers to any medium that participates in providing instructions to the processor(s) 802 for execution, including without limitation, non-volatile media (e.g., optical or magnetic disks), volatile media (e.g., memory) and transmission media. Transmission media includes, without limitation, coaxial cables, copper wire, and fiber optics.

Computer-readable medium(s) 808 can further include instructions 812 for an operating system (e.g., Mac OS® server, Windows® NT server, Linux Server), instructions 814 for network communications module, data processing instructions 816, and interface instructions 818.

Operating systems can be multi-user, multiprocessing, multitasking, multithreading, real time, etc. Operating system performs basic tasks, including but not limited to: recognizing input from and providing output to devices 802, 804, 806 and 808; keeping track and managing files and directories on computer-readable medium(s) 808 (e.g., memory or a storage device); controlling peripheral devices; and managing traffic on the one or more communication channel(s) 810. Network communications module includes various components for establishing and maintaining network connections (e.g., software for implementing communication protocols, such as TCP/IP, HTTP, etc.) and for creating a distributed streaming platform using, for example, Apache Kafka™. Data processing instructions 816 include server-side or backend software for implementing the server-side operations. Interface instructions 818 includes software for implementing a web server and/or portal for sending and receiving data to and from user side computing devices and service side computing devices.

Architecture 800 can be implemented by a cloud computing system and can be included in any computer device, including one or more server computers in a local or distributed network each having one or more processing cores. Architecture 800 can be implemented in a parallel processing or peer-to-peer infrastructure or on a single device with one or more processors. Software can include multiple software components or can be a single body of code.

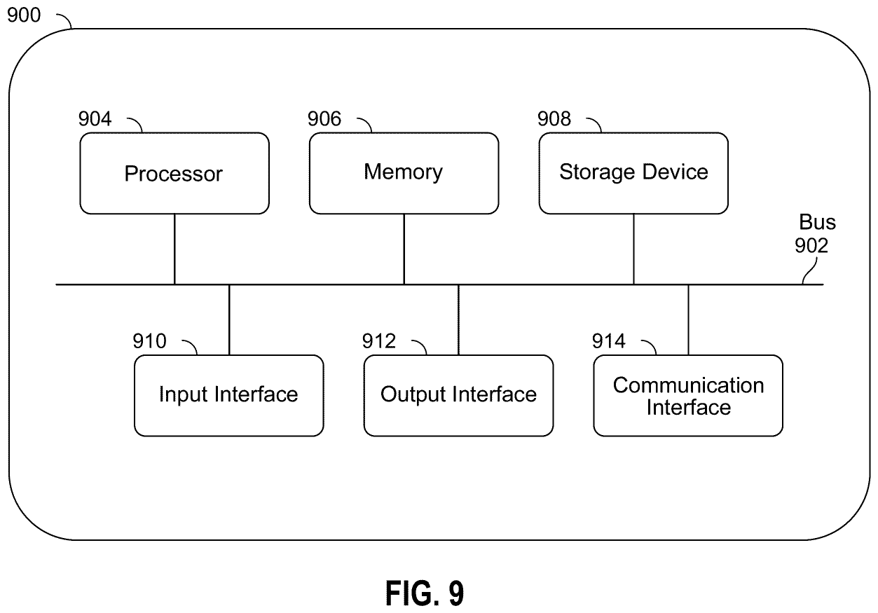

FIG. 9 is a block diagram illustrating an example architecture of a computing device 900 used to provide computational functionalities associated with described algorithms, methods, functions, processes, flows, and procedures. Other architectures are possible, including architectures with more or fewer components.

The computing device 900 includes processor 904, memory 906, storage component 908, input interface 910, output interface 912, communication interface 914, and bus 902. The computing device 900 includes a PCB (e.g., the PCB of FIG. 1, the PCB 200 of FIG. 2, the PCB 301 of FIG. 3, the PCB 401 of FIG. 4, or the PCB 501 of FIG. 5). The processor 904, memory 906, storage component 908, input interface 910, output interface 912, communication interface 914, and bus 902 can be integrated on the PCB and can communicate using the PCB.

Bus 902 includes a component that permits communication among the components of the computing device 900. In some implementations, processor 904 is implemented in hardware, software, or a combination of hardware and software. In some examples, processor 904 includes a processor (e.g., a central processing unit (CPU), a graphics processing unit (GPU), an accelerated processing unit (APU), and/or the like), a microphone, a digital signal processor (DSP), and/or any processing component (e.g., a field-programmable gate array (FPGA), an application specific integrated circuit (ASIC), and/or the like) that can be programmed to perform at least one function. Memory 906 includes random access memory (RAM), read-only memory (ROM), and/or another type of dynamic and/or static storage device (e.g., flash memory, magnetic memory, optical memory, and/or the like) that stores data and/or instructions for use by processor 904.

Storage component 908 stores data and/or software related to the operation and use of the computing device 900. In some examples, storage component 908 includes a hard disk (e.g., a magnetic disk, an optical disk, a magneto-optic disk, a solid state disk, and/or the like), a compact disc (CD), a digital versatile disc (DVD), a floppy disk, a cartridge, a magnetic tape, a CD-ROM, RAM, PROM, EPROM, FLASH-EPROM, NV-RAM, and/or another type of computer readable medium, along with a corresponding drive.

Input interface 910 includes a component that permits the computing device 900 to receive information, such as via user input (e.g., a touchscreen display, a keyboard, a keypad, a mouse, a button, a switch, a microphone, a camera, and/or the like). Additionally or alternatively, in some embodiments input interface 910 includes a sensor that senses information (e.g., a global positioning system (GPS) receiver, an accelerometer, a gyroscope, an actuator, and/or the like). Output interface 912 includes a component that provides output information from the computing device 900 (e.g., a display, a speaker, one or more light-emitting diodes (LEDs), and/or the like).

In some implementations, communication interface 914 includes a transceiver-like component (e.g., a transceiver, a separate receiver and transmitter, and/or the like) that permits the computing device 900 to communicate with other devices via a wired connection, a wireless connection, or a combination of wired and wireless connections. In some examples, communication interface 914 permits the computing device 900 to receive information from another device and/or provide information to another device. In some examples, communication interface 914 includes an Ethernet interface, an optical interface, a coaxial interface, an infrared interface, a radio frequency (RF) interface, a universal serial bus (USB) interface, a Wi-Fi® interface, a cellular network interface, and/or the like.

In some implementations, the computing device 900 performs one or more processes described herein. The computing device 900 performs these processes based on processor 904 executing software instructions stored by a computer-readable medium, such as memory 906 and/or storage component 908. A computer-readable medium (e.g., a non-transitory computer readable medium) is defined herein as a non-transitory memory device. A non-transitory memory device includes memory space located inside a single physical storage device or memory space spread across multiple physical storage devices.

In some implementations, software instructions are read into memory 906 and/or storage component 908 from another computer-readable medium or another device via communication interface 914. When executed, software instructions stored in memory 906 and/or storage component 908 cause processor 904 to perform one or more processes described herein. Additionally or alternatively, hardwired circuitry is used in place of or in combination with software instructions to perform one or more processes described herein. Thus, embodiments described herein are not limited to any specific combination of hardware circuitry and software unless explicitly stated otherwise.

Memory 906 and/or storage component 908 includes data storage or at least one data structure (e.g., a database and/or the like). The computing device 900 is capable of receiving information from, storing information in, communicating information to, or searching information stored in the data storage or the at least one data structure in memory 906 or storage component 908. In some examples, the information includes network data, input data, output data, or any combination thereof.

In some implementations, the computing device 900 is configured to execute software instructions that are either stored in memory 906 and/or in the memory of another device (e.g., another device that is the same as or similar to the computing device 900). As used herein, the term “module” refers to at least one instruction stored in memory 906 and/or in the memory of another device that, when executed by processor 904 and/or by a processor of another device (e.g., another device that is the same as or similar to the computing device 900) cause the computing device 900 (e.g., at least one component of the computing device 900) to perform one or more processes described herein. In some implementations, a module is implemented in software, firmware, hardware, and/or the like.

The number and arrangement of components illustrated in FIG. 9 are provided as an example. In some implementations, the computing device 900 can include additional components, fewer components, different components, or differently arranged components than those illustrated in FIG. 9. Additionally or alternatively, a set of components (e.g., one or more components) of the computing device 900 can perform one or more functions described as being performed by another component or another set of components of the computing device 900.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs, that is, one or more modules of computer program instructions encoded on a tangible, non-transitory, computer-readable medium for execution by, or to control the operation of, a computer or computer-implemented system. Alternatively, or additionally, the program instructions can be encoded in/on an artificially generated propagated signal, for example, a machine-generated electrical, optical, or electromagnetic signal that is generated to encode information for transmission to a receiver apparatus for execution by a computer or computer-implemented system. The computer-storage medium can be a machine-readable storage device, a machine-readable storage substrate, a random or serial access memory device, or a combination of computer-storage mediums. Configuring one or more computers means that the one or more computers have installed hardware, firmware, or software (or combinations of hardware, firmware, and software) so that when the software is executed by the one or more computers, particular computing operations are performed. The computer storage medium is not, however, a propagated signal.

The term “real-time,” “real time,” “realtime,” “real (fast) time (RFT),” “near(ly) real-time (NRT),” “quasi real-time,” or similar terms (as understood by one of ordinary skill in the art), means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

The terms “data processing apparatus,” “computer,” “computing device,” or “electronic computer device” (or an equivalent term as understood by one of ordinary skill in the art) refer to data processing hardware and encompass all kinds of apparatuses, devices, and machines for processing data, including by way of example, a programmable processor, a computer, or multiple processors or computers. The computer can also be, or further include special-purpose logic circuitry, for example, a central processing unit (CPU), a field-programmable gate array (FPGA), or an application-specific integrated circuit (ASIC). In some implementations, the computer or computer-implemented system or special-purpose logic circuitry (or a combination of the computer or computer-implemented system and special-purpose logic circuitry) can be hardware- or software-based (or a combination of both hardware- and software-based). The computer can optionally include code that creates an execution environment for computer programs, for example, code that constitutes processor firmware, a protocol stack, a database management system, an operating system, or a combination of execution environments. The present disclosure contemplates the use of a computer or computer-implemented system with an operating system, for example LINUX, UNIX, WINDOWS, MAC OS, ANDROID, or IOS, or a combination of operating systems.

A computer program, which can also be referred to or described as a program, software, a software application, a unit, a module, a software module, a script, code, or other component can be written in any form of programming language, including compiled or interpreted languages, or declarative or procedural languages, and it can be deployed in any form, including, for example, as a stand-alone program, module, component, or subroutine, for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files, for example, files that store one or more modules, sub-programs, or portions of code. A computer program can be deployed to be executed on one computer or on multiple computers that are located at one site or distributed across multiple sites and interconnected by a communication network.

While portions of the programs illustrated in the various figures can be illustrated as individual components, such as units or modules, that implement described features and functionality using various objects, methods, or other processes, the programs can instead include a number of sub-units, sub-modules, third-party services, components, libraries, and other components, as appropriate. Conversely, the features and functionality of various components can be combined into single components, as appropriate. Thresholds used to make computational determinations can be statically, dynamically, or both statically and dynamically determined.

Described methods, processes, or logic flows represent one or more examples of functionality consistent with the present disclosure and are not intended to limit the disclosure to the described or illustrated implementations, but to be accorded the widest scope consistent with described principles and features. The described methods, processes, or logic flows can be performed by one or more programmable computers executing one or more computer programs to perform functions by operating on input data and generating output data. The methods, processes, or logic flows can also be performed by, and computers can also be implemented as, special-purpose logic circuitry, for example, a CPU, an FPGA, or an ASIC.

Computers for the execution of a computer program can be based on general or special-purpose microprocessors, both, or another type of CPU. Generally, a CPU will receive instructions and data from and write to a memory. The essential elements of a computer are a CPU, for performing or executing instructions, and one or more memory devices for storing instructions and data. Generally, a computer will also include, or be operatively coupled to, receive data from or transfer data to, or both, one or more mass storage devices for storing data, for example, magnetic, magneto-optical disks, or optical disks. However, a computer need not have such devices. Moreover, a computer can be embedded in another device, for example, a mobile telephone, a personal digital assistant (PDA), a mobile audio or video player, a game console, a global positioning system (GPS) receiver, or a portable memory storage device, for example, a universal serial bus (USB) flash drive, to name just a few.

Non-transitory computer-readable media for storing computer program instructions and data can include all forms of permanent/non-permanent or volatile/non-volatile memory, media and memory devices, including by way of example semiconductor memory devices, for example, random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices; magnetic devices, for example, tape, cartridges, cassettes, internal/removable disks; magneto-optical disks; and optical memory devices, for example, digital versatile/video disc (DVD), compact disc (CD)-ROM, DVD+/−R, DVD-RAM, DVD-ROM, high-definition/density (HD)-DVD, and BLU-RAY/BLU-RAY DISC (BD), and other optical memory technologies. The memory can store various objects or data, including caches, classes, frameworks, applications, modules, backup data, jobs, web pages, web page templates, data structures, database tables, repositories storing dynamic information, or other appropriate information including any parameters, variables, algorithms, instructions, rules, constraints, or references. Additionally, the memory can include other appropriate data, such as logs, policies, security or access data, or reporting files. The processor and the memory can be supplemented by, or incorporated in, special-purpose logic circuitry.

To provide for interaction with a user, implementations of the subject matter described in this specification can be implemented on a computer having a display device, for example, a cathode ray tube (CRT), liquid crystal display (LCD), light emitting diode (LED), or plasma monitor, for displaying information to the user and a keyboard and a pointing device, for example, a mouse, trackball, or trackpad by which the user can provide input to the computer. Input can also be provided to the computer using a touchscreen, such as a tablet computer surface with pressure sensitivity or a multi-touch screen using capacitive or electric sensing. Other types of devices can be used to interact with the user. For example, feedback provided to the user can be any form of sensory feedback (such as, visual, auditory, tactile, or a combination of feedback types). Input from the user can be received in any form, including acoustic, speech, or tactile input. In addition, a computer can interact with the user by sending documents to and receiving documents from a client computing device that is used by the user (for example, by sending web pages to a web browser on a user's mobile computing device in response to requests received from the web browser).

The term “graphical user interface (GUI) can be used in the singular or the plural to describe one or more graphical user interfaces and each of the displays of a particular graphical user interface. Therefore, a GUI can represent any graphical user interface, including but not limited to, a web browser, a touch screen, or a command line interface (CLI) that processes information and efficiently presents the information results to the user. In general, a GUI can include a number of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server, or that includes a front-end component, for example, a client computer having a graphical user interface or a Web browser through which a user can interact with an implementation of the subject matter described in this specification, or any combination of one or more such back-end, middleware, or front-end components. The components of the system can be interconnected by any form or medium of wireline or wireless digital data communication (or a combination of data communication), for example, a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) using, for example, 802.11x or other protocols, all or a portion of the Internet, another communication network, or a combination of communication networks. The communication network can communicate with, for example, Internet Protocol (IP) packets, frame relay frames, Asynchronous Transfer Mode (ATM) cells, voice, video, data, or other information between network nodes.

The computing system can include clients and servers. A client and server are generally remote from each other and typically interact through a communication network. The relationship of client and server arises by virtue of computer programs running on the respective computers and having a client-server relationship to each other.

The separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

While this specification contains many specific implementation details, these should not be construed as limitations on the scope of any inventive concept or on the scope of what can be claimed, but rather as descriptions of features that can be specific to particular implementations of particular inventive concepts. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features can be described as acting in certain combinations and even initially claimed as such, one or more features from a claimed combination can, in some cases, be excised from the combination, and the claimed combination can be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations can be considered optional), to achieve desirable results. In certain circumstances, multitasking or parallel processing (or a combination of multitasking and parallel processing) can be advantageous and performed as deemed appropriate.

What is claimed is:

1. A device, comprising:
a first layer comprising first electrically conductive traces;
a second layer comprising second electrically conductive traces; and
a core layer stacked between the first layer and the second layer, the core layer comprising:
a dielectric material filled in the core layer; and
groups of optical fibers that are embedded in the filled dielectric material and extend across the core layer.

2. The device of claim 1, further comprising fiber connectors,
wherein each of the fiber connectors is coupled to a respective group of the groups of optical fibers embedded in the filled dielectric material of the core layer, and
wherein each group of optical fibers has input ends coupled to a first fiber connector and output ends coupled to a second fiber connector.

3. The device of claim 2, wherein the first layer, the core layer, and the second layer form a group of layers, and
wherein at least one of the first fiber connector or the second fiber connector is arranged on a side of the group of layers.

4. The device of claim 2, wherein at least one of the first fiber connector or the second fiber connector is arranged on or in the first layer.

5. The device of claim 1, wherein the first layer, the core layer, and the second layer are stacked along a first direction,
wherein the groups of optical fibers comprise first groups of optical fibers extending along a second direction perpendicular to the first direction and second groups of optical fibers extending along a third direction perpendicular to the first direction and the second direction, and
wherein the core layer extends in a plane defined by the second direction and the third direction, the first direction being perpendicular to the plane.

6. The device of claim 1, wherein the core layer further comprises fillers distributed within the filled dielectric material and around the groups of optical fibers.

7. The device of claim 1, wherein the dielectric material comprises a polymer material.

8. The device of claim 1, wherein the core layer further comprises glass fibers that are embedded in the filled dielectric material and extend across the core layer.

9. The device of claim 1, further comprising:
one or more other core layers between the first layer and the second layer; and
one or more intermediate layers between the first layer and the second layer, each of the one or more intermediate layers being between two adjacent core layers.

10. The device of claim 1, wherein the device is configured to be a printed circuit board (PCB).

11. A device, comprising:
a printed circuit board (PCB), comprising:
a first layer comprising first electrically conductive traces;
a second layer comprising second electrically conductive traces; and
a core layer stacked between the first layer and the second layer, wherein the core layer comprises: a dielectric material filled in the core layer and groups of optical fibers that are embedded in the filled dielectric material and extend across the core layer; and
circuits integrated on the PCB and configured to communicate with one another using at least one of the groups of optical fibers in the core layer.

12. The device of claim 11, wherein the PCB further comprises fiber connectors,
wherein each of the fiber connectors is coupled to a respective group of the groups of optical fibers embedded in the filled dielectric material of the core layer, and
wherein each group of optical fibers has input ends coupled to a first fiber connector and output ends coupled to a second fiber connector.

13. The device of claim 12, wherein the circuits comprise:
a first optical circuit coupled to a corresponding first fiber connector of the fiber connectors; and
a second optical circuit coupled to a corresponding second fiber connector of the fiber connectors,
wherein the first optical circuit and the second optical circuit are configured to transmit data through the corresponding first fiber connector, the corresponding second fiber connector, and at least one corresponding group of optical fibers coupled between the corresponding first fiber connector and the corresponding second fiber connector.

14. The device of claim 12, wherein the circuits comprise: a first electrical circuit and a second electrical circuit,
wherein the device further comprises:
an electric-optical (E/O) converter coupled to the first electrical circuit and a corresponding first fiber connector of the fiber connectors, wherein the first electrical circuit is coupled to the corresponding first fiber connector through the E/O converter;
a photodetector coupled to the second electrical circuit and a corresponding second fiber connector of the fiber connectors, wherein the second electrical circuit is coupled to the corresponding second fiber connector through the photodetector, and
wherein the first electrical circuit is configured to transmit an electrical signal to the second electrical circuit through the E/O converter, the corresponding fiber connector, at least one corresponding group of optical fibers coupled between the corresponding first fiber connector and the corresponding second fiber connector, the corresponding second fiber connector, and the photodetector.

15. The device of claim 14, wherein the circuits further comprise a third electrical circuit, and wherein at least one of the first electrical circuit or the second electrical circuit is coupled to the third electrical circuit through at least one of one or more of the first electrically conductive traces or one or more of the second electrically conductive traces.

16. The device of claim 15, wherein the first electrical circuit and the second electrical circuit are configured to transmit first electrical data with each other using a first data rate,
wherein the at least one of the first electrical circuit or the second electrical circuit is configured to transmit second electrical data with the third electrical circuit using a second data rate, and
wherein the first data rate is greater than the second data rate.

17. The device of claim 12, wherein the circuits comprise: an optical circuit and an electrical circuit configured to communicate with each other through at least one corresponding group of optical fibers of the groups of optical fibers.

18. The device of claim 17, further comprising:
an electric-optical (E/O) converter coupled to the electrical circuit and a corresponding first fiber connector of the fiber connectors that is coupled to the at least one corresponding group of optical fibers,
wherein the optical circuit is coupled to a corresponding second fiber connector of the fiber connectors that is coupled to the at least one corresponding group of optical fibers, and
wherein the electrical circuit is configured to transmit an electrical signal to the optical circuit through the E/O converter, the corresponding first fiber connector, the at least one corresponding group of optical fibers, and the corresponding second fiber connector.

19. The device of claim 17, further comprising:
a photodetector coupled to the electrical circuit and a corresponding first fiber connector of the fiber connectors that is coupled to the at least one corresponding group of optical fibers,
wherein the optical circuit is coupled to a corresponding second fiber connector of the fiber connectors that is coupled to the at least one corresponding group of optical fibers, and
wherein the optical circuit is configured to transmit an optical signal to the electrical circuit through the corresponding second fiber connector, the at least one corresponding group of optical fibers, the corresponding first fiber connector, and the photodetector.

20. A method, comprising:
providing groups of optical fibers;
forming a core layer by embedding the groups of optical fibers in a dielectric material, wherein the groups of optical fibers extend across the core layer;
forming a first layer comprising first electrically conductive traces and a second layer comprising second electrically conductive traces; and
integrating the first layer, the core layer, and the second layer together to form a device.
